(19) United States
(12) Patent Application Publication
(10) Pub. No.: US 2025/0286001 A1
(43) Pub. Date: Sep. 11, 2025

(54) PAD METALLIZATION SYSTEMS AND RELATED METHODS

(71) Applicant: SEMICONDUCTOR COMPONENTS INDUSTRIES, LLC, Scottsdale, AZ (US)

(72) Inventors: Michael J. SEDDON, Gilbert, AZ (US); Guy BRIZAR, Oosterzele (BE); Do Hyung KIM, Vaterstetten (DE)

(73) Assignee: SEMICONDUCTOR COMPONENTS INDUSTRIES, LLC, Scottsdale, AZ (US)

(21) Appl. No.: 19/213,197

(22) Filed: May 20, 2025

Related U.S. Application Data
(63) Continuation-in-part of application No. 18/446,127, filed on Aug. 8, 2023.

(51) Int. Cl. H01L 23/00; H01L 23/29; H01L 23/31

(52) U.S. Cl. CPC H01L 24/05; H01L 23/291; H01L 23/293; H01L 23/3171; H01L 23/3192; H01L 24/03; H01L 24/04; H01L 24/45; H01L 2224/0345; H01L 2224/03452; H01L 2224/03462; H01L 2224/03464; H01L 2224/04042; H01L 2224/05005; H01L 2224/05124; H01L 2224/05147; H01L 2224/05155; H01L 2224/05541; H01L 2224/05624; H01L 2224/05644; H01L 2224/05664; H01L 2224/05666; H01L 2224/05681; H01L 2224/05687; H01L 2224/0569; H01L 2224/45014; H01L 2924/3511; H01L 2924/3512

(57) ABSTRACT

Implementations of a method of forming an interconnect may include providing a semiconductor substrate including a plurality of aluminum pads thereon, each pad surrounded by a passivation material; forming a barrier layer over the pads and the passivation material; and forming a seed layer over the barrier layer. The method may include patterning a layer of photoresist with a plurality of openings exposing the pads; forming a copper layer at least 18 microns thick over each of the pads by electroplating into each opening of the plurality of openings; and forming a nickel layer at least 5 microns thick over the copper layer. The method may include forming one of a gold layer or a palladium layer over the nickel layer; removing the layer of photoresist; etching the barrier layer and the seed layer to form a copper-containing interconnects; and bonding one of a ribbon bond or a bond wire.

### CROSS REFERENCE TO RELATED APPLICATIONS

This application is a continuation-in-part application of the earlier U.S. Utility Patent Application to Seddon et al., entitled “Copper Pad Metallization Systems and Related Methods,” application Ser. No. 18/446,127 filed Aug. 8, 2023, now pending, the disclosure of which is hereby incorporated entirely herein by reference.

### BACKGROUND

### 1. Technical Field

Aspects of this document relate generally to methods for forming electrical interconnects. More specific implementations involve electrical interconnects that include copper pads.

### 2. Background

Semiconductor packages have been devised that allow for routing of electrical signals from a semiconductor die to components of the package used to interface with a circuit board or motherboard to which the semiconductor package is attached. Semiconductor packages also have been developed that assist with protecting the semiconductor die from humidity, thermal conditions, or shock and vibration during operation and use.

### SUMMARY

Implementations of a method of forming an interconnect may include providing a semiconductor substrate including a plurality of aluminum silicon copper pads thereon, each pad surrounded by a passivation material; forming a barrier layer over the plurality of aluminum silicon copper pads and the passivation material, and forming a seed layer over the barrier layer. The method may include patterning a layer of photoresist with a plurality of openings exposing the plurality of aluminum silicon copper pads; forming a copper layer at least 18 microns thick over each of the aluminum silicon copper pads by electroplating into each opening of the plurality of openings; and forming a nickel layer at least 5 microns thick over the copper layer. The method may include forming one of a gold layer or a palladium layer over the nickel layer; removing the layer of photoresist; etching the barrier layer and the seed layer to form a plurality of copper-containing interconnects; and bonding one of a ribbon bond or a bond wire at least 254 microns thick to one of the gold layer or the palladium layer.

Implementations of a method of forming an interconnect may include one, all, or any of the following:

Forming the copper layer, the nickel layer, and the one of the gold layer or the palladium layer on each aluminum silicon copper pad of the plurality of aluminum silicon copper pads further may include forming using electrolytic plating.

The semiconductor substrate may include silicon carbide.

Forming the barrier layer or the seed layer further may include using sputtering.

The method may include forming a backmetal on the semiconductor substrate.

Each aluminum silicon copper pad of the plurality of aluminum silicon copper pads may be formed of a top layer of aluminum silicon copper that contacts the barrier layer and a bottom layer of aluminum silicon copper.

The top layer of aluminum silicon copper may be 1 micron thick.

Implementations of a method of forming an interconnect may include providing a semiconductor substrate including a plurality of aluminum pads thereon, each pad surrounded by a passivation material; forming a barrier layer over the plurality of aluminum pads and the passivation material; and forming a seed layer over the barrier layer. The method may include patterning a layer of photoresist with a plurality of openings exposing the plurality of aluminum pads; forming a copper layer at least 18 microns thick over each of the aluminum pads by electroplating into each opening of the plurality of openings; and forming a nickel layer at least 5 microns thick over the copper layer. The method may include forming one of a gold layer or a palladium layer over the nickel layer; removing the layer of photoresist; etching the barrier layer and the seed layer to form a plurality of copper-containing interconnects; and bonding one of a ribbon bond or a bond wire at least 254 microns thick to one of the gold layer or the palladium layer.

Implementations of a method of forming an interconnect may include one, all, or any of the following:

Forming the copper layer, the nickel layer, and the one of the gold layer or the palladium layer on each aluminum pad of the plurality of aluminum pads further may include forming using electrolytic plating.

The semiconductor substrate may include silicon carbide.

Forming the barrier layer or the seed layer further may include using sputtering.

The method may include forming a backmetal on the semiconductor substrate.

Each aluminum pad of the plurality of aluminum pads may be formed of a top layer of aluminum that contacts the barrier layer and a bottom layer of aluminum.

The top layer of aluminum may be 1 micron thick.

Implementations of a method of forming an interconnect may include providing a semiconductor substrate including a plurality of aluminum-containing pads thereon, each pad surrounded by a passivation material; forming a barrier layer over the plurality of aluminum-containing pads and the passivation material; and forming a seed layer over the barrier layer. The method may include patterning a layer of photoresist with a plurality of openings exposing the plurality of aluminum-containing pads; forming a first copper layer over each of the aluminum-containing pads by electroplating into each opening of the plurality of openings; and forming a first nickel layer over the first copper layer. The method may include forming a second copper layer over the first nickel layer by electroplating into each opening of the plurality of openings; forming a second nickel layer over the second copper layer; forming one of a gold layer or a palladium layer over the second nickel layer; and removing the layer of photoresist. The method may include etching the barrier layer and the seed layer to form a plurality of copper-containing interconnects; and bonding one of a ribbon bond or a bond wire at least 254 microns thick to one of the gold layer or the palladium layer.

Implementations of a method of forming an interconnect may include one, all, or any of the following:

The combined thickness of the barrier layer, seed layer, first copper layer, first nickel layer, second copper layer, second nickel layer, and the one of the gold layer or palladium layer may be sufficient to successfully complete the bonding of the one of the ribbon bond or the bond wire.

The first copper layer and the second copper layer may be 10 microns thick.

The first nickel layer and the second nickel layer may be between 3 microns and 4 microns thick.

The method may include forming a backmetal layer on a surface of the semiconductor substrate opposing a surface of the semiconductor substrate including the plurality of aluminum-containing pads.

Each aluminum-containing pad of the plurality of aluminum-containing pads may be formed of a top layer that contacts the barrier layer and a bottom layer and where the top layer may be 1 micron thick.

The foregoing and other aspects, features, and advantages will be apparent to those artisans of ordinary skill in the art from the DESCRIPTION and DRAWINGS, and from the CLAIMS.

### BRIEF DESCRIPTION OF THE DRAWINGS

Implementations will hereinafter be described in conjunction with the appended drawings, where like designations denote like elements, and:

FIG. 1 is a side cross sectional view of an implementation of a semiconductor substrate with pads formed thereon;

FIG. 2 is a side cross sectional view of the implementation of the semiconductor substrate of FIG. 1 following deposition of a seed layer;

FIG. 3 is a side cross sectional view of the implementation of the semiconductor substrate of FIG. 2 following formation of a photoresist pattern thereon;

FIG. 4 is a side cross sectional view of the implementation of the semiconductor substrate of FIG. 3 following electroplating of copper pads thereon;

FIG. 5 is a side cross sectional view of the implementation of the semiconductor substrate of FIG. 4 following formation of one or more layers over the exposed surface of the copper pad and removal of the photoresist;

FIG. 6 is a side cross sectional view of the implementation of the semiconductor substrate of FIG. 5 following etching/removal of the seed layer;

FIG. 7 is a side cross sectional view of the implementation of the semiconductor substrate of FIG. 6 following formation of a patterned polyimide layer over the copper pads;

FIG. 8 is a side cross sectional view of the implementation of the semiconductor substrate of FIG. 7 after formation of an additional layer on the exposed portion of the copper pad;

FIG. 9 is a side cross sectional view of another implementation of a semiconductor substrate with pads formed thereon;

FIG. 10 is a side cross sectional view of the implementation of the semiconductor substrate of FIG. 9 with a seed layer formed thereon;

FIG. 11 is a side cross sectional view of the implementation of the semiconductor substrate of FIG. 10 following formation of a photoresist pattern thereon;

FIG. 12 is a side cross sectional view of the implementation of the semiconductor substrate of FIG. 11 following electroplating of copper pads thereon;

FIG. 13 is a side cross sectional view of the implementation of the semiconductor substrate of FIG. 12 following removal of the photoresist and application of a layer to the top surfaces of the copper pads;

FIG. 14 is a side cross sectional view of the implementation of the semiconductor substrate of FIG. 13 following removal of the seed layer;

FIG. 15 is a side cross sectional view of the implementation of the semiconductor substrate of FIG. 14 following formation of a patterned polyimide layer over the copper pads and etching/removal of the layer over the top surface of the copper pad;

FIG. 16 is a side cross sectional view of the implementation of the semiconductor substrate of FIG. 13 following formation of a patterned polyimide layer over the copper pads;

FIG. 17 is a side cross sectional view of the implementation of the semiconductor substrate of FIG. 12 following removal of the photoresist layer and seed layer;

FIG. 18 is a side cross sectional view of the implementation of the semiconductor substrate of FIG. 17 following formation of a patterned polyimide layer over the copper pads;

FIG. 19 is a side cross sectional view of the implementation of the semiconductor substrate of FIG. 18 following formation of a metal layer over the exposed portion of the copper pad;

FIG. 20 is a cross sectional view of an implementation of a semiconductor substrate following formation of a patterned polyimide layer over aluminum silicon copper pads;

FIG. 21 is a cross sectional view of the implementation of the semiconductor substrate of FIG. 20 following deposition of a barrier layer and a seed layer thereon;

FIG. 22 is a cross sectional view of the implementation of the semiconductor substrate of FIG. 21 following formation of a layer of photoresist thereon;

FIG. 23 is a cross sectional view of the implementation of the semiconductor substrate of FIG. 22 following patterning of the layer of photoresist;

FIG. 24 is a cross sectional view of the implementation of the semiconductor substrate of FIG. 23 following electroplating of a copper layer, a nickel layer, and a gold layer or a palladium layer on the seed layer;

FIG. 25 is a cross sectional view of the implementation of the semiconductor substrate of FIG. 24 following removal of the layer of photoresist;

FIG. 26 is a cross sectional view of the implementation of the semiconductor substrate of FIG. 25 following etching of the seed layer and the barrier layer and formation of a backmetal layer thereon;

FIG. 27 is a cross sectional view of an implementation of a semiconductor substrate that includes planarized pads thereon;

FIG. 28 is a cross sectional view of an implementation of a semiconductor substrate illustrating thick nickel layers;

FIG. 29 is a cross sectional view of an implementation of a semiconductor substrate with planarized pads thereon illustrating thick nickel layers;

FIG. 30 is a cross sectional view of an implementation of a semiconductor substrate with interconnects with multiple copper and multiple nickel layers;

FIG. 31 is a cross sectional view of an implementation of a semiconductor substrate with a ribbon bond bonded to two interconnects thereon; and

FIG. 32 is a cross sectional view an implementation of a semiconductor substrate with a thick bond wire wirebonded to a interconnect thereon.

### DESCRIPTION

This disclosure, its aspects and implementations, are not limited to the specific components, assembly procedures or method elements disclosed herein. Many additional components, assembly procedures and/or method elements known in the art consistent with the intended copper pad metallization systems will become apparent for use with particular implementations from this disclosure. Accordingly, for example, although particular implementations are disclosed, such implementations and implementing components may comprise any shape, size, style, type, model, version, measurement, concentration, material, quantity, method element, step, and/or the like as is known in the art for such copper pad metallization systems, and implementing components and methods, consistent with the intended operation and methods.

In various semiconductor devices, logic circuits and power circuits can be combined. For example, in the case of a semiconductor device used to operate an automatic window opener in an automobile, the logic portion of the device senses the control signal indicating the window is to be raised or lowered and then activates the power portion (a metal oxide field effect transistor [MOSFET]) to transfer power to the motor for the specified period of time to allow the window to physically be raised or lowered. The voltage and power used by the logic portion of the device is typically much smaller in comparison with the voltage and power needed to operate the motor, so if the electrical interconnects used for the logic portion are used for the power portion of the device, the electrical interconnects can be damaged through overheat and/or excessive current load, even during the relatively short time that the high voltage/amperage is experienced during operation. In such systems, electrical interconnects adapted for higher power operation, such as thick copper interconnects like pads/bumps/pillars greater than 10 microns in height can be used to help the interconnects avoid damage during the high voltage transient load period. Similar structures in the form of metal lines greater than 10 microns in height are also used, and the principles disclosed herein can also be applied with metal lines. As wirebonding is often used to connect the source and drain pads of the MOSFET, for example, the ability to create reliable wirebonds with a wire bondable material of the thick copper interconnects is a design consideration when such combined logic and power circuits are combined in a semiconductor device.

In some process implementations, thick copper pads with a layer of gold and/or nickel on their upper surface are used. Since the sidewalls of the thick copper pads remain exposed in this process, the likelihood that particulate contamination can cause shorting between pads is increased as there is nothing present to fill the gaps between adjacent pads. In other process implementations, to assist with reducing the likelihood that particulate contamination can cause failures with the thick copper pads, the use of polyimide layers that fill in the space between the pads and cover the upper surface of the thick copper pillars is used in applications such as, by non-limiting example, automotive and other vehicle industries. Openings in the polyimide layer to expose the upper portion of the thick copper pillars are made into which the wirebonds are formed. In order to get the polyimide to adhere to the gold on the upper surface of the thick copper pads however, a film of palladium needs to be used as the top layer over the upper surface. The polyimide can also adhere to a layer of aluminum formed at the top layer over the upper surface of the thick copper pads, but does not adhere to the gold of the thick copper pads themselves.

Various methods for forming thick copper interconnect systems are disclosed in this document that utilize various layers of materials to which a polyimide material will adhere over the top surface of a thick copper pad/bump/pillar. These methods are merely exemplary, and combinations of these methods and materials disclosed herein may be employed in various system and method implementations. While in this document the term “pads” is used primarily to describe the methods and structures herein, it should be understood that the same principles may be applied with other metallization structures including bond pads, metal lines, or other large areas of metallization like dummy structures used to ensure local and wafer-level uniformity.

One of the challenges of forming wirebonds with pure copper pads is that the presence of copper oxide on the bond surface of the pads interferes with the formation of the intermetallic and alloy compounds that form a good mechanical and electrical connection between the bond wire and the copper pads. Thus, the ability to minimize and reduce the formation of copper oxide during the processing steps assists with the creation of good wirebonds. The various methods implementations disclosed herein show various approaches to reduce copper oxide formation on the bond surface/top surface of the copper pads disclosed herein.

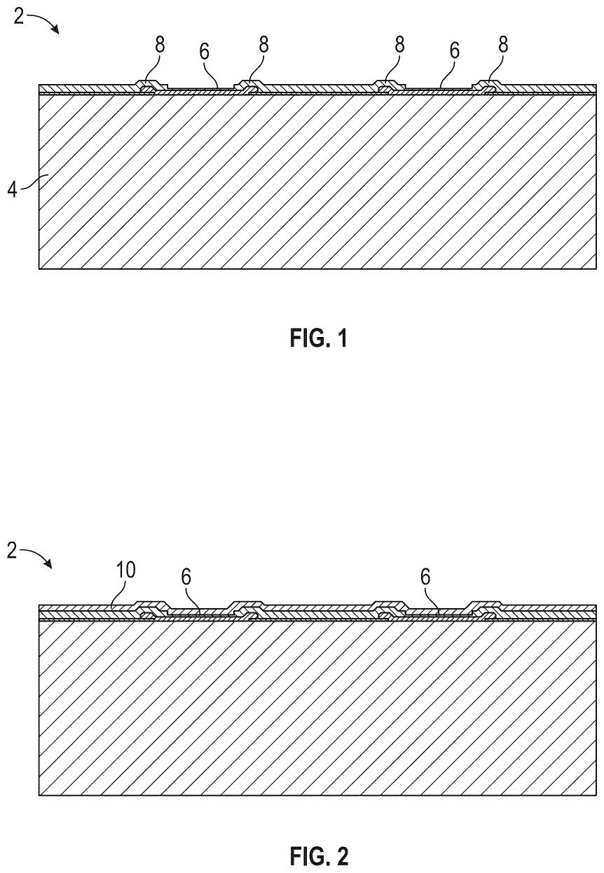

Referring to FIG. 1, a side cross sectional view of a semiconductor device 2 is illustrated which includes semiconductor substrate portion 4 on which is formed a plurality of pads 6. These pads 6 represent the outer layer of a stack of materials that are formed on/in the semiconductor substrate portion 4 which, for the sake of easier illustration, are not shown in FIG. 1 or the other figures, but are understood to be present as forming the active device(s) included in the semiconductor device 2. This stack of material helps forms structures such as, by non-limiting example, transistors, diodes, interconnects, traces, vias, insulating layers, and any other component of an active semiconductor device. Around each of the pads 6 is a layer of passivation material 8 which may be, by non-limiting example, silicon nitride, a polyimide, or another electrically insulating material. The particular material of the semiconductor substrate may be, by non-limiting example, silicon, silicon carbide, silicon on insulator, ruby, sapphire, gallium arsenide, gallium nitride, or any other semiconductor material type. The particular types of semiconductor devices that may employ the method implementations disclosed here may include, by non-limiting example, transistors, MOSFETs, insulated gate bipolar transistors (IGBTs), diodes, power devices, high electron mobility transistors (HEMTs), rectifiers, or any other power semiconductor device or other active semiconductor device type. While in FIG. 2 just two pads are illustrated, it is understood that this is merely for illustration convenience as the method implementations disclosed may be employed at the die-level or wafer-level portions of the fabrication process and many more pads than just two pads may be employed in various implementations.

Referring to FIG. 2, a side cross sectional view of the semiconductor device 2 of FIG. 1 is illustrated following formation of a seed layer 10 thereon for use in electroplating. The use of the seed layer 10 permits the formation of an electrical connection to the seed layer material covering each of the pads 6 during the electroplating operation. In various implementations, the seed layer 10 may be formed by sputtering. The seed layer 10 may include, by non-limiting example, a titanium and tungsten film, a copper film, any combination thereof, or another metal film type that permits electroplating of pure copper to the seed layer.

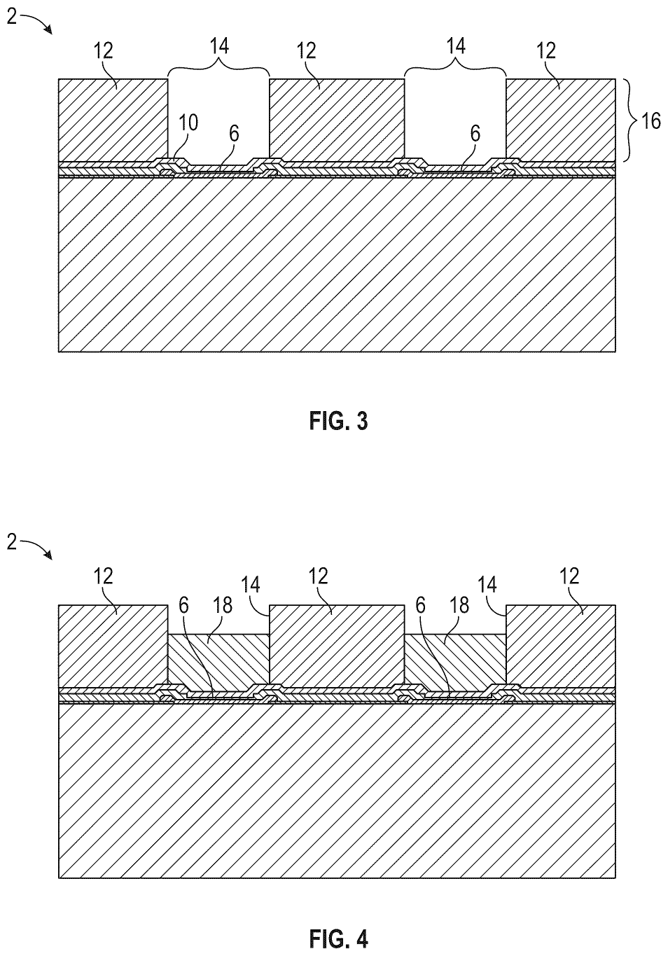

Following formation of the seed layer 10, referring to FIG. 3, a layer of photoresist 12 is applied which is then patterned. The application process for the photoresist 12 may include, by non-limiting example, spin coating, dispensing, stencil printing, squeegee application, or any other method for forming a uniform layer of material above the seed layer 10. The patterning process used may be specific to the particular type of photoresist employed. For example, where a positive photoresist is employed, the regions of the photoresist above the pads 6 are exposed with an electromagnetic radiation source through a mask to cause a corresponding reaction in the material of the photoresist that permits a developing solution to wash away the exposed regions. Where a negative photoresist is employed, the regions of the photoresist outside the pads are exposed to electromagnetic radiation causing a corresponding reaction in the material of the photoresist that prevents the developing solution from washing away the exposed regions. As illustrated in FIG. 3, the openings 14 in the photoresist 12 are larger than the size of the pads to allow the passivation material and any other under bump materials to assist in supporting the to-be-formed bump and help prevent issues like bump cracking later during operation. However, in other implementations, the size of the openings 14 may be the same as or substantially the same as the size of the pads. The height/thickness 16 of the photoresist 12 is set to be higher than or substantially the same as the height of the copper pads to be electroplated to help form the sidewalls and a flat upper/bonding surface for each of the copper pads.

Referring to FIG. 4, the semiconductor device 2 is illustrated following completion of the electroplating process that forms a copper pad/bump/pillar 18 within each of the openings 14 of the photoresist 12 which is mechanically and electrically connected with each corresponding pad 6. In this implementation, a pure copper pad has been formed, meaning that substantially all of the material of the pad is formed of just copper. In other implementations, however, a copper alloy could be electroplated, depending on the electrical or mechanical characteristics desired for the pads.

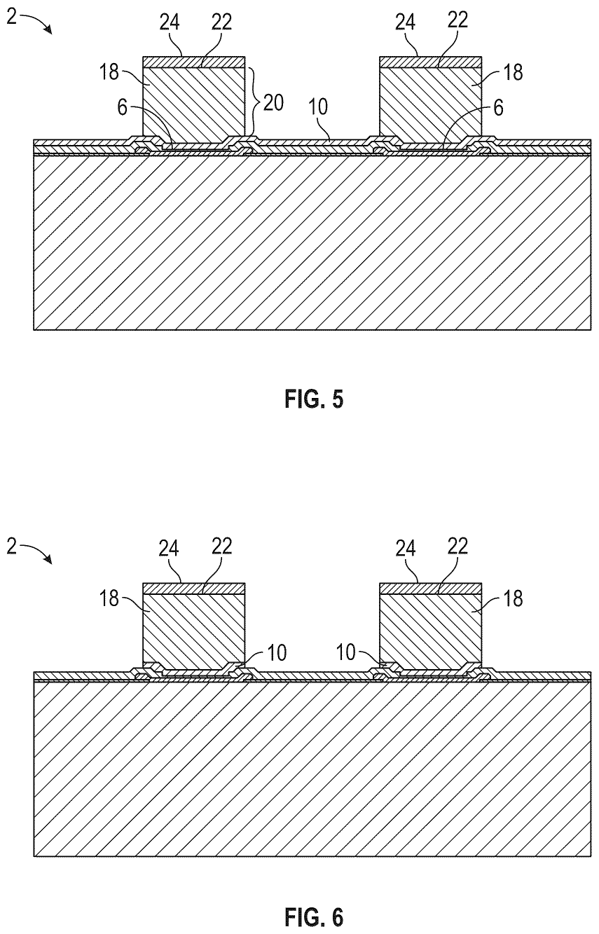

Referring to FIG. 5, the semiconductor device is illustrated following formation of one or more layers of material 24 on the top side/bonding surface 22 of each of the copper bumps 18 and after stripping/removal of the photoresist. In various method implementations, the one or more layers may be formed using electroless plating. Where the one or more layers are formed using electroless plating, the electroless plating may be carried out while the photoresist is still present around the copper pads 18 as illustrated in FIG. 4 after electroplating of the copper pads. In other implementations however, the electroless plating may take place after the photoresist has been removed and after removal of the seed layer 10 as in the structure illustrated in FIG. 6. While the one or more layers 24 are illustrated as being present on only the top of the copper pads 18 in FIG. 5 for ease of illustration, where the electroless plating takes place after removal of the photoresist and seed layer, it is understood that the material of the one or more layers may deposit on all exposed surface of each of the copper pads 18. Thus, if the one or more layers 24 are desired to be formed only on the bonding surface 22 of the copper pads 18, then the electroless plating would take place while the photoresist 12 is still in place as illustrated in FIG. 4.

While the previous discussion discloses the use of electroless plating to form the one or more layers of material 24, in other method implementations, sputtering may be used to form the one or more layers of material 24. In such implementations, the sputtering takes place following the electroplating of the copper pads 18 while the photoresist 12 is still in place around the pads as illustrated in FIG. 14. The photoresist 12 is then stripped/removed as previously described, leaving the one or more layer of material 24 on the bond surface 22 of each of the copper pads 18 as illustrated in FIG. 5.

The materials used in the one or more layers of material 24 depend on the particular method of formation. Where electroless plating is employed, the material of the one or more layers may be nickel, gold, or palladium as a single layer in some implementations. In others, the material of the one or more layers may be nickel, gold, or palladium in two or more separate layers each formed through electroless plating. In yet other implementations, the material of the one or more layers may be any combination of nickel, gold, and/or palladium formed in a single layer or in multiple layers using electroless plating. Where the use of sputtering is employed, the material of the one or more layers may be, by non-limiting example, either titanium, nickel, and gold or titanium, nickel, and palladium formed in either a single layer or as separate layers.

The process of removing the photoresist may take place using various methods, including, by non-limiting example, solvent stripping, washing, ashing, etching, or any other method for removing polymer material. As illustrated, the as-plated copper pads 18 are then exposed and rise above the surface of the seed layer 10 at a desired height/thickness 20. As the seed layer 10 electrically shorts all of the copper pads 18 and all of the pads 6 together, it needs to be removed to electrically isolate all of the pads 6 from each other once again.

Referring to FIG. 6, the semiconductor device 2 of FIG. 5 is illustrated following removal of the seed layer material 10 from around the copper pads 18, leaving the seed layer 10 present only as an under bump material of each of the copper pads. The removal of the seed layer 10 may be carried out using etching in various method implementations. FIG. 6 also illustrates that, after the seed layer 10 has been removed, the one or more layers of material 24 remain formed onto the top surface/bonding surface 22 of each of the copper pads 18. In various implementations, the one or more layers of material 24 may be formed of a material that is not removed/etched by the process used to remove/etch the seed layer.

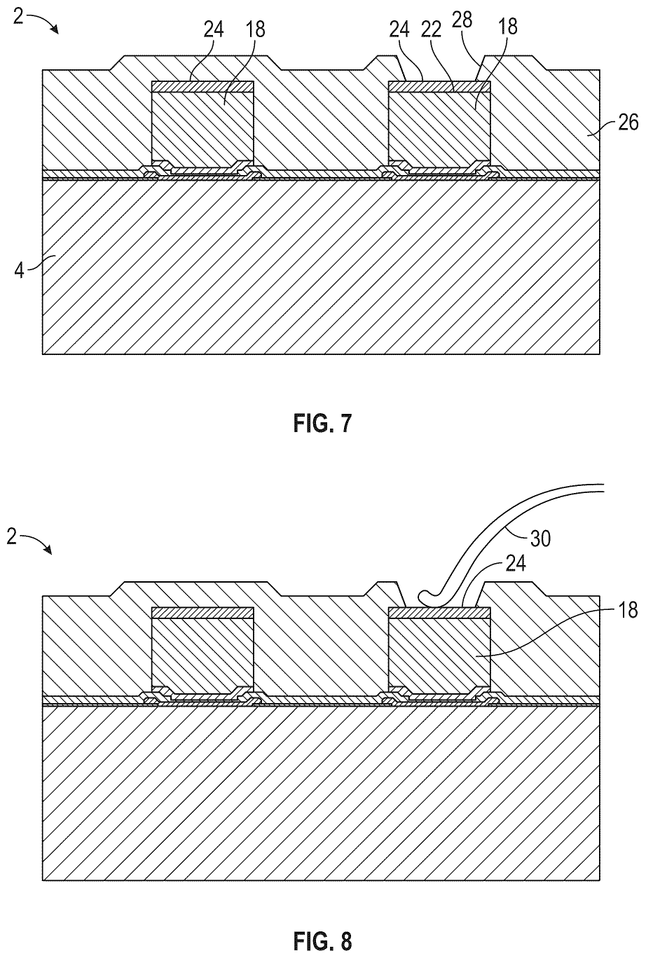

Referring to FIG. 7, the semiconductor device 2 is illustrated following application of a layer of polyimide 26 over the copper pads 18 and the patterning of opening 28 over the top surface/bonding surface 22. Note that not every copper pad 18 may have the top surface 22 with the one or more layers of material 24 exposed through an opening in the layer of polyimide 26. This may be because not all of the pads 6 are actually used for electrical interconnects and may be dummy pads used to preserve a certain amount of metal density at the pad layer to help improve processing uniformity or to help provide mechanical support/strength to the semiconductor device. The particular patterning method and process used to form the opening 28 in the polyimide 26 depends on the material of the polyimide and whether it is patterned photolithographically using positive or negative exposure processes like those previously described in this document. Because material types used in the one or more layers of material 24 are those previously described in this document, the polyimide 26 will adhere to the one or more layers 24 to form the opening 28 and allow for wirebonding into the opening 28. FIG. 8 illustrates the semiconductor device 2 following wire bonding of a bond wire 30 onto the one or more materials 24 and to the copper pad 18.

Prior to the wirebonding process, the semiconductor device 2 may have the semiconductor substrate portion thinned through, by non-limiting example, backgrinding, lapping, separating, polishing, or any other thinning process. Because of the use of the polyimide 26, the mechanical strength of the remaining portion of the semiconductor substrate portion may be improved to support a thinner die than could otherwise be produced without the presence of the polyimide 26 in the material stack. A wide variety of method variations may be constructed using the principles disclosed in this document.

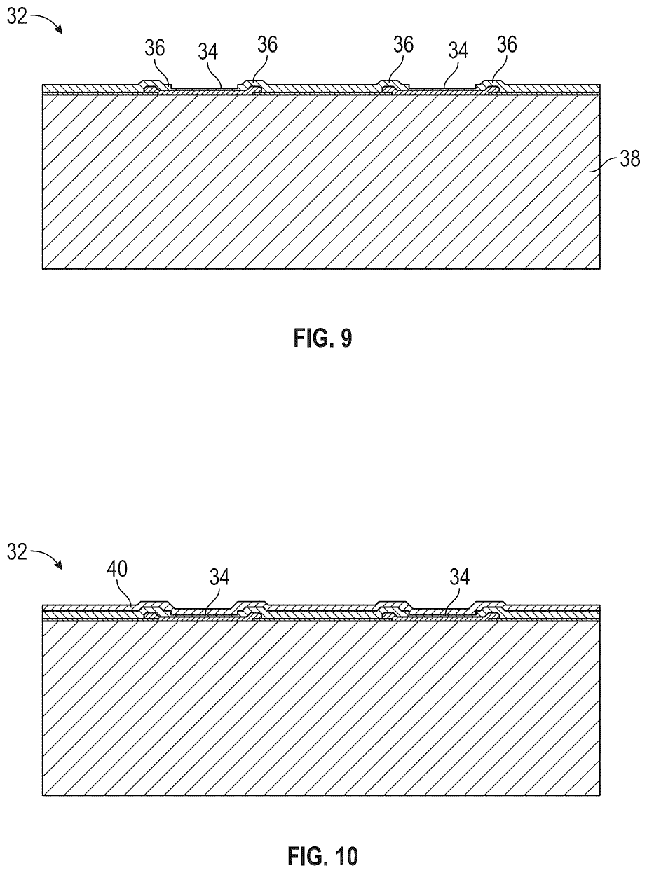

Referring to FIG. 9, a second semiconductor device 32 is illustrated in a side cross sectional view that is similar in structure to the semiconductor device 2 of FIG. 1. The semiconductor device 32 includes pads 34 which are surrounded by passivation material 36. In the various method implementations, the material of the semiconductor substrate portion 38 of the semiconductor device 32 may be any disclosed in this document. In the various method implementations, the material of the passivation material 36 may also be any disclosed in this document. Also, the semiconductor device 32 may be any semiconductor device type disclosed in this document.

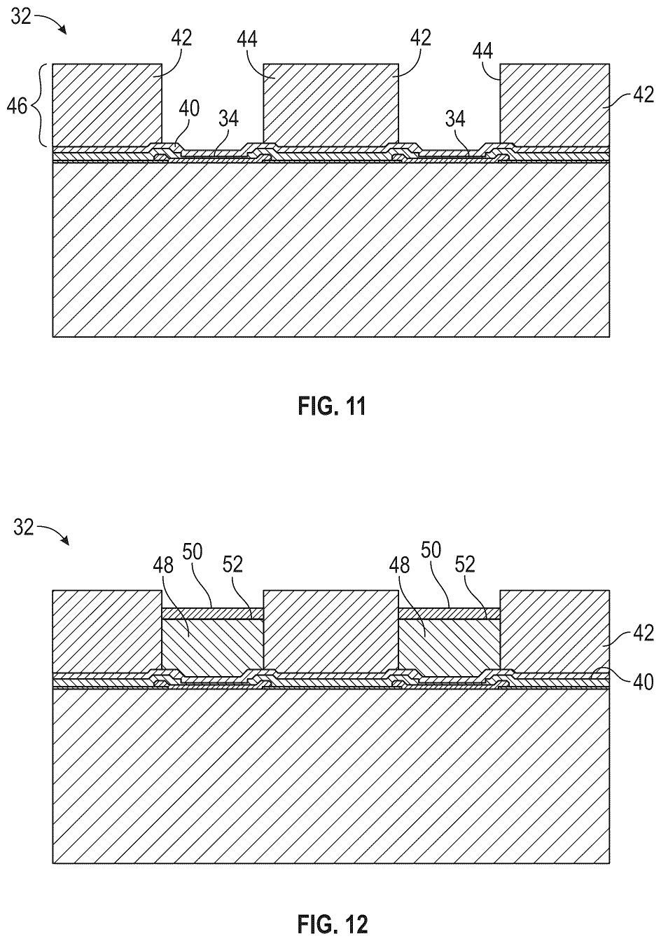

Referring to FIG. 10, the semiconductor device 32 is illustrated in a side cross sectional view following formation of a seed layer 40 over the pads 34. The material of the seed layer 40 may be any disclosed in this document used for seed layers for electroplating copper. FIG. 11 illustrates the semiconductor device 32 following formation of a patterned layer of photoresist 42 over the seed layer 40 with openings 44 over the pads 34. The material of the photoresist 42 may be any disclosed in this document and may be patterned using any of the patterning method implementations disclosed herein in various method implementations. The height/thickness 46 of the photoresist 42 above the seed layer 40 is again set at a level to achieve/support formation of copper pads at a desired thickness during electroplating.

Referring to FIG. 12, the semiconductor device 32 is illustrated in a side cross sectional view following electroplating of copper pads 48. The electroplating process for forming the copper pads 48 and the material of the copper pads 48 may be any disclosed in this document. FIG. 12 also illustrates the semiconductor device 32 following the formation of one or more layers 50 over the top surface/bonding surface 52 of each of the copper pads 48. In various method implementations, the one or more layers 50 may include different materials formed and processed using corresponding methods. In a particular implementation, the one or more layers 50 is an organic coating that, when applied, prevents or substantially prevents reaction of oxygen with the newly plated copper of the copper pads 48, thus reducing the formation of copper oxide on the bonding surface 52. This organic coating is applied soon after the completion of the electroplating of the copper pads, thus helping to seal the bonding surface 52 of the copper pads 48 from reacting further with oxygen. Furthermore, the organic coating is a material to which a subsequently applied polyimide material will adhere. Also, the organic material in this implementation is one that a wirebond can be formed through during the wirebonding process and does not involve a cleaning or removal step.

In another implementation, the one or more layers 50 is an organic material that is thicker or more tightly bonded to the copper layer than the previously disclosed organic material of the previous method implementation. This organic material has the same ability to prevent further formation of copper oxide on the bonding surface 52 of the copper bumps 48, but needs to be removed/cleaned from the bonding surface 52 prior to the actual wirebonding using a cleaning step that will be discussed hereafter. In various implementations, the organic materials that may be employed in either method implementations may be organic solderability preservatives marketed by RBP Chemical Technology Inc. of Milwaukee, WI; MacDermid Alpha Electronics Solutions of Waterbury, CT; or Shikoku Chemicals Corporation of Marugame, Kagawa, Japan.

In another implementation, the one or more layers 50 is a layer of aluminum that is deposited on the bonding surface 52 that reacts with oxygen immediately to form aluminum oxide (alumina). In particular implementations, the layer of alumina is deposited using atomic layer deposition and may be between 1 to 5 atoms thick. In other implementations, however, other materials other aluminum may be used in the one or more layer 50, such as, by non-limiting example, titanium nitride, tantalum nitride, any combination thereof, or other material capable of being deposited using ALD. Such a layer is sufficiently thick to prevent diffusion of oxygen to the copper pad 48 and the formation of copper oxide but thin enough to be wire bonded through during the wirebonding process. In various method implementations where atomic layer deposition is employed, the aluminum is deposited while the photoresist 42 is present in the atomic layer deposition chamber leading to the structure illustrated in FIG. 12. In other implementations, however, the aluminum may be deposited after the photoresist 42 has been stripped from the seed layer 40 but before the seed layer 40 is etched. This may take place to avoid issues with outgassing or contamination of the process from the large thickness of photoresist present after the electroplating process has been completed. The aluminum adds the additional benefit in that a subsequently applied polyimide will adhere to the aluminum layer.

In other method implementations, a layer of aluminum between about 1 to about 4 microns is sputtered to form the one or more layers 50. In some implementations, the layer of aluminum may be about 2 microns thick. The layer of aluminum, when applied soon after plating of the copper, may assist with reducing copper oxide formation and also assist with adhesion of the polyimide subsequently formed over the copper pads.

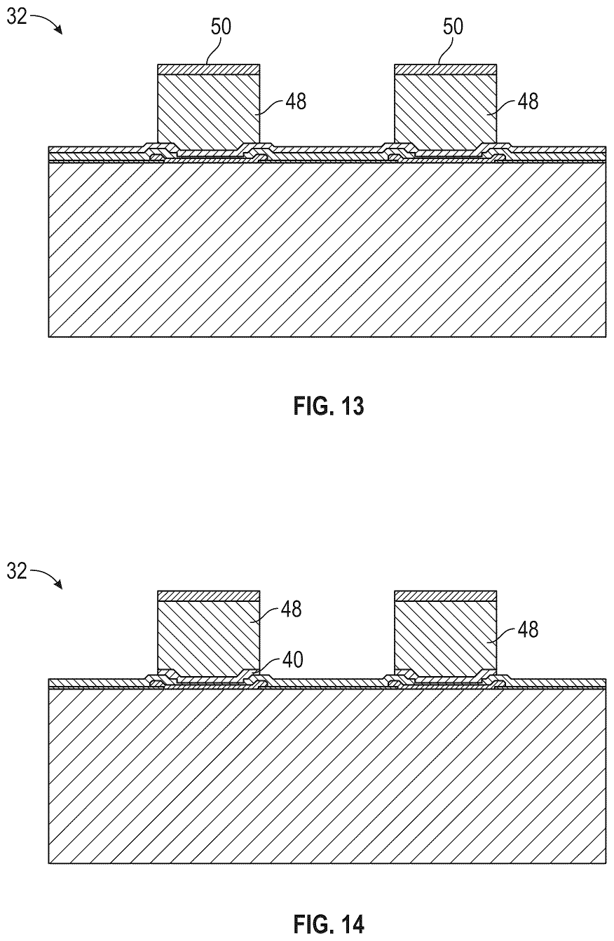

Referring to FIG. 13, the semiconductor device 32 is illustrated in a side cross sectional view following removal of the photoresist. In the various method implementations, the photoresist may be removed using any of the methods disclosed in this document. In FIG. 13, the one or more layers 50 illustrated of the copper pads 48 may be either of the organic materials previously mentioned or the layer of aluminum deposited using atomic layer deposition previously discussed. FIG. 14 illustrates the semiconductor device 32 following removal of exposed portions of the seed layer 40 that are not part of the copper pads 48. The removal of the seed layer 40 may take place using any of the methods disclosed herein. In various methods, the particular removal method may also take into account the resistance of the material present of the one or more layers 50 to the particular removal method. In some implementations where the aluminum layer is present which was applied after removal of the photoresist, causing the aluminum to be deposited on the seed layer 40, a removal method that is capable of removing the aluminum either separately initially or in combination with the material of the seed layer 40 may be employed.

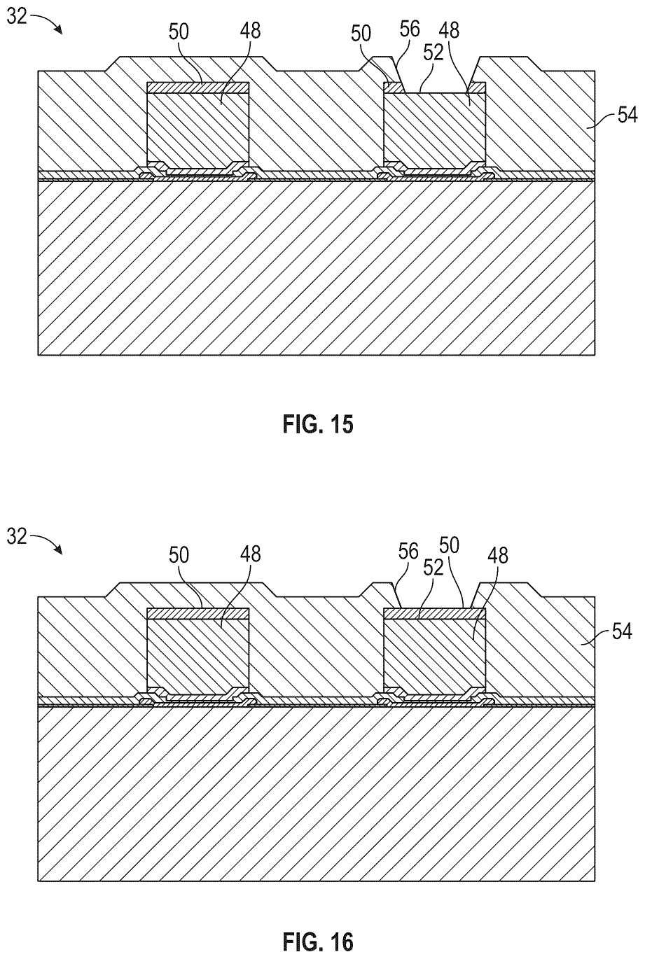

Referring to FIG. 15, the semiconductor substrate 32 is illustrated following application of a polyimide layer 54 over the copper pads 48 and patterning of that layer to form opening 56. FIG. 15 is a side cross sectional view following removal of the material of the one or more layers 50 that exposed through the opening 56. In this method implementation, the material of the one or more layers 50 is the organic material that needs to be removed/cleaned from the bonding surface 52 of the copper pads 48 prior to wirebonding. In this method implementation, because the organic material cannot be bonded through, it needs to be removed following the formation of the polyimide layer 54 while still providing adhesion to the bonding surface 52 of the copper pads 48 for the polyimide.

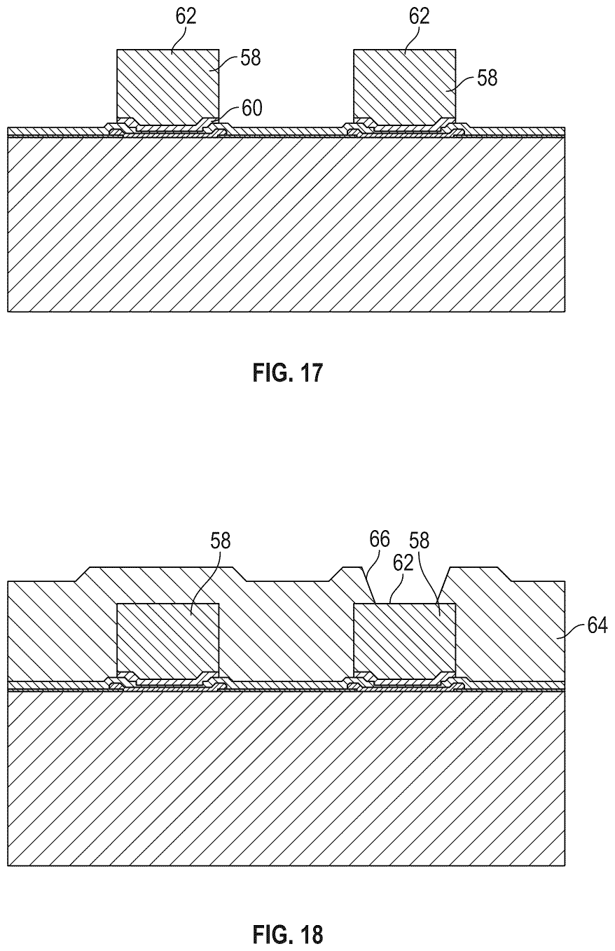

FIG. 16 illustrates an alternative structure that results from an alternative method implementation used where the aluminum layer or the organic coating forms the one or more layers 50 formed over the bonding surface 52. As in FIG. 15, a polyimide layer 54 has been formed over the copper pads 48 and patterned using any of the methods disclosed herein to form opening 56. However, the exposed material of the one or more layers 50 is not removed in this method implementation and so wire bonding takes place by bonding through either the organic coating or the aluminum layer formed by atomic layer deposition. In this way, the bond is not affected by copper oxide while a pure copper pad is still being bonded to while the polyimide layer 54 is still able to adhere to the bonding surface 52 of each of the copper pads 48.

Referring to FIG. 17, copper pads 58 are illustrated after removal of the photoresist as illustrated in FIG. 12 and after etching of the seed layer 60. In this method implementation, however, no layer is applied over the top/bonding surface 62 of the copper pads following formation and prior to etching of the seed layer 60, leaving the top/bonding surface 62 as copper. FIG. 18 illustrates the copper pads 58 of FIG. 17 following formation of a polyimide layer 64 and formation of opening 66 to expose the top/bonding surface 62. In some method implementations, the polyimide layer 64 sufficiently sticks/bonds with the top/bonding surface 62 of the copper pads 58 so that no additional layer is applied to the top/bonding surface 62. In such implementations, the bonding is then carried out directly onto the top/bonding surface 62.

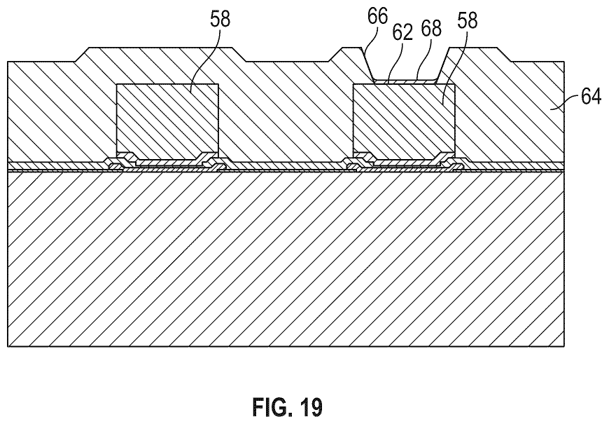

In other method implementations, like the one illustrated in FIG. 19, following forming the opening 66 in the polyimide 64, one or more layers 68 is formed over the top/bonding surface 62 of the copper pad 58. In some implementations, electroless plating may be used to form a layer of nickel, a layer of palladium, a layer of gold, or any combination thereof to form the one or more layers 68. In other implementations, sputtering may be used to apply titanium and aluminum (either as separate layers or a single layer) to form the one or more layers 68. In other implementations, sputtering may be used to apply titanium tungsten and aluminum (either as separate layers or a single layer) to form the one or more layers 68. In yet other implementations, atomic layer deposition may be employed to form the one or more layers 68 of any of the materials disclosed herein used for atomic layer deposition. As illustrated in FIG. 19, where sputtering is used to form the one or more layers 68, the material of the one or more layers 68 may rise up around the edges of the polyimide layer 64 of the opening 66.

A wide variety of possible combinations of electroless plated/sputtered/atomic layer deposition may be employed to form various layers on the top/bonding layer 62 of the copper pads 58 in various method implementations.

The various semiconductor device implementations disclosed in the subsequent discussion in this document relate to devices made specifically with silicon carbide or gallium nitride substrates specifically. However, the principles involving thick copper and nickel layers could be applied to other substrate types including silicon, silicon-on-insulator, gallium arsenide, sapphire, or ruby. Thus, while in the foregoing discussion reference is made to silicon carbide and gallium nitride substrates, it should be understood that the principles disclosed also apply to other semiconductor substrate types.

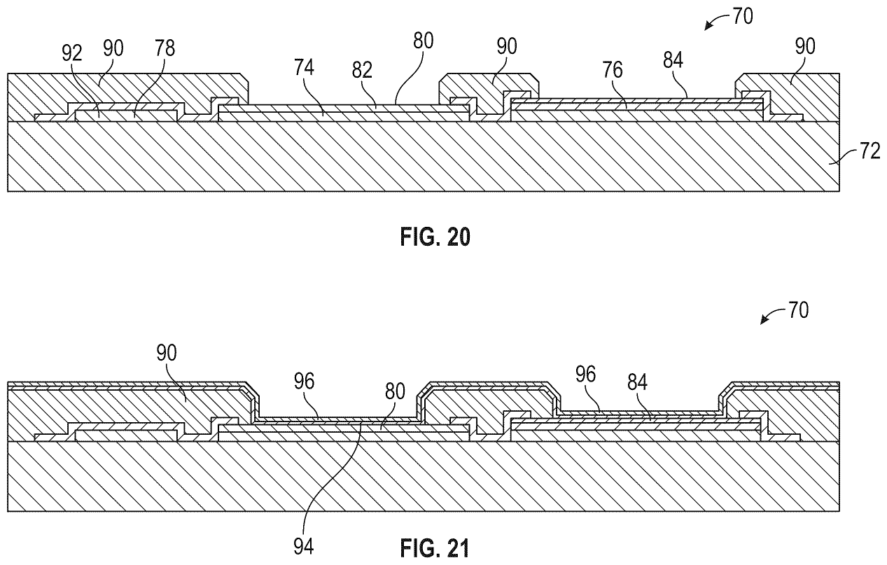

Referring to FIG. 20, an implementation of a power metal oxide field effect transistor (MOSFET) 70 is illustrated with just the far backend interconnect layers shown on the semiconductor substrate 72 and with the remaining interconnect/device layers under metal 1 below these layers and formed in the substrate not shown for the purposes of more clear illustration. While a power MOSFET device is illustrated in FIG. 20, the principles disclosed herein could be employed with any other silicon carbide or gallium nitride (or other substrate type) semiconductor device type (diode, high electron mobility transistor, power semiconductor device, rectifier, etc.) that utilizes pads for forming subsequent interconnects with a circuit/motherboard using wirebonds, bumps, or pillars.

In FIG. 20, a source pad 74, gate pad 76, and a gate runner 78 are illustrated. The source pad 74 includes a first layer of aluminum silicon copper 80 and a second layer of aluminum silicon copper 82. Gate pad 76 includes a first layer of aluminum silicon copper 84 and a second layer of aluminum silicon copper 86 separated by gate oxide layer 88. In this implementation, gate runner 78 is made of a single layer of aluminum silicon copper, though in other implementations two layers of aluminum silicon copper could be used. The gate runner 78 is routed away from the source pad 74 and gate pad 76, which means that part of the surface area of the power MOSFET device is dedicated to the location of the gate runner.

In a particular power MOSFET device design, aluminum silicon copper pads are disclosed. However, the discussion also applies to other pad types that include aluminum (aluminum silicon or aluminum only pads, aluminum-containing pads). In this implementation, the thickness of the first layer of aluminum silicon copper 80 of the pads is about 3 microns and the total thickness of the two layers is about 7 microns to about 10 microns. During temperature cycling reliability testing designed to simulate operation of the power MOSFET over its entire design lifetime, recrystallization of the aluminum silicon copper and corresponding deformation of the first and second layers of aluminum silicon copper 80, 82 has been observed during failure analysis. The deformation has been observed to be so significant that cracking of the passivation layers on the die edge and dielectric layer material cracking in gate runner structures next/under the source pad has been observed. Where an electroless plated nickel palladium gold layer is plated over the first layer of aluminum silicon copper 80, 84, cracking of the nickel palladium gold layer has also been observed during known good die testing due to softening of the aluminum silicon copper layers caused by heating of the layers which permits recrystallization and corresponding deformation to begin.

To combat the interlayer dielectric cracking around the gate runner, the gate runner 78 can be routed a sufficient distance away from the source pad 74, but this increases the total surface area needed for the power MOSFET device thus increasing the die size. Also, where soldering is used to attach to the nickel palladium gold layer the nickel can become fully consumed in the joint forming process or during subsequent operation of the device which creates a weak joint between the aluminum silicon copper layer and the solder which can result in device failure. The silicon carbide MOSFETs disclosed herein may be operated in harsher application environments that demand higher power dissipation and/or continuous operation at about 185 C to about 200 C. Under these conditions, the degradation of the electroless plated nickel palladium gold in combination with the deformation of the about 5 micron thick first and second layers of aluminum silicon copper 80, 82 for the source pad 74 may cause enough failures during reliability testing indicating that field failure likelihood is unacceptably high.

To combat the deformation of the first and second aluminum silicon copper layers, reduction of the thickness of the first layer 80 is disclosed in this document. Elimination of electroless plated layers and the use of electroplated layers is also disclosed herein. Also, in a particular method and systems implementation, the use of only aluminum in the pad layers instead of aluminum silicon copper or aluminum silicon is disclosed.

Referring back to FIG. 20, in this power MOSFET implementation 70, the thickness of the first layer of aluminum silicon copper 80 is between about 1 micron to about 2 microns instead of about 3 microns. The ability to reduce the thickness of the first layer of aluminum silicon copper correspondingly reduces the likelihood of heat-induced deformation. It also results in a reduction of the cost to form the interconnects as less aluminum silicon copper material is needed in the interconnect structure. This reduction of the thickness of the first layer of aluminum silicon copper is facilitated by the use of the electroplated layers. In the implementation of FIG. 20, the combined thickness of the first layer of aluminum silicon copper 80 and the second layer of aluminum silicon copper 80 may be between about 7 microns to about 10 microns.

In FIG. 20, a layer of passivation material 90 is illustrated formed around the gate runner 78, source pad 74, and gate pad 76. In this implementation the passivation material is a photodefinable polyimide (PDPI) material which is initially applied over the pads and then exposed and developed to form openings through which the source pad 74 and gate pad 76 are exposed. While the use of a polyimide is illustrated in FIG. 20, in other implementations materials like a die coat material or a benzocyclobutene (BCB) material could be utilized as well. In some implementations, a hard passivation material could also be used, though the use of a compliant polymeric material may aid with handling stresses during temperature cycling caused during operation. As illustrated in FIG. 20, an additional layer(s) of passivation material 92 may also be formed over the gate runner 78 and adjacent to the source pad 74 and gate pad 76. In this implementation, the passivation material 92 is a hard passivation material (in this case silicon nitride).

The various device structure implementations disclosed herein may be formed using various implementations of a method of forming an interconnect. Referring to FIG. 21, the power MOSFET implementation 70 of FIG. 20 is illustrated following formation of barrier layer 94 over the passivation material 90 and first layer of aluminum silicon copper 80 of the source pad 74 and the first layer of aluminum silicon copper 84 of the gate pad 76. The barrier layer 94 may be formed of, by non-limiting example, titanium tungsten, titanium tungsten nitride, titanium nitride, any combination thereof, or another material designed to prevent diffusion of copper into the die stack materials and material of the silicon carbide substrate. FIG. 21 also illustrates seed layer 96 that has been formed over the barrier layer 94. In this implementation, the seed layer 96 is made of copper to facilitate copper electroplating. Because the seed layer is deposited over the entire surface of the substrate, electrical connections needed to electroplate copper are present on the substrate.

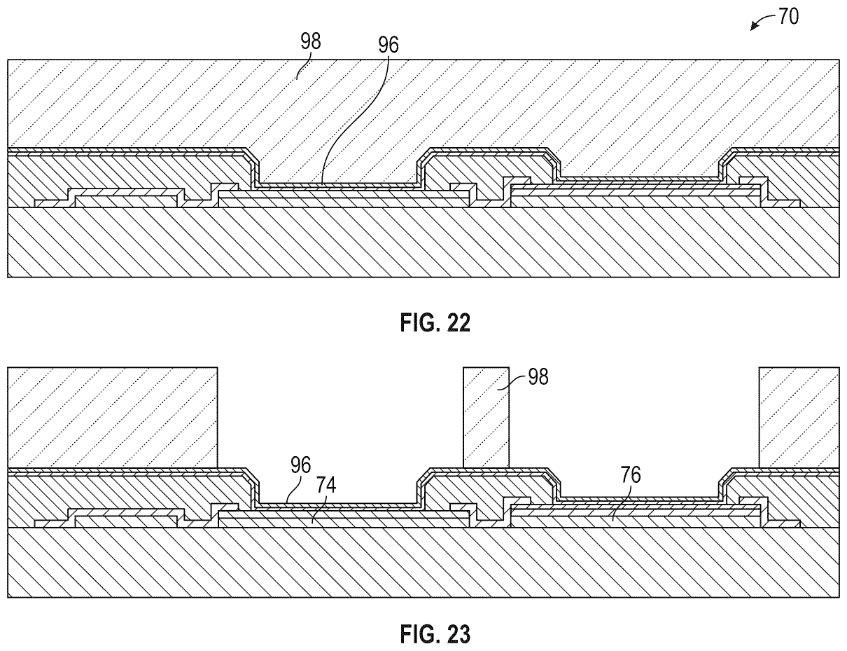

Referring to FIG. 22, the power MOSFET implementation 70 is illustrated following application of a layer of photoresist 98 over the seed layer 96. The thickness of the layer of photoresist may be determined by the desired thickness of the metal layer(s) that will be electroplated onto the seed layer in various method implementations. The layer of photoresist may be formed using spin coating, stencil printing, squeegeeing, or through a dry film application. FIG. 23 illustrates the layer of photoresist 98 following patterning using a lithographic exposure and develop process. The unexposed (in the case of negative photoresist) or exposed (in the case of a positive photoresist) material is removed to expose the source pad 74 and gate pad 76 with the seed layer 96 thereon. At this point, the power MOSFET implementation 70 is ready for electroplating.

One of the challenges of developing interconnects for power semiconductor devices, particularly high power devices, is finding a way to reliably handle the transfer of high amperages and high voltages to and from the power semiconductor device. Because the layers fabricated on the die can be an order to two orders of magnitude smaller than the pins, bond wires, clips and other mechanical interconnect structures used in a power semiconductor package, a mechanical strength mismatch can occur. Bonding components like ribbon bonds or thick bond wires with diameters of about 10 mils (254 microns) to about 12 mils (304.8 microns) or greater are capable of carrying the higher amperages/voltages needed by the power semiconductor die in the package. However, such bonding components have a size difference that presents significant integration challenges into the package when attempting to directly couple them to the power semiconductor die themselves. As discussed throughout this document, the use of pads formed during fabrication processing is often used with power semiconductor devices to form the die-side interconnect with an external electrical interconnect used for power transfer and/or signal routing. In this document, various pad systems and methods of forming interconnects capable of directly coupling with ribbon bonds and thick bond wires are disclosed.

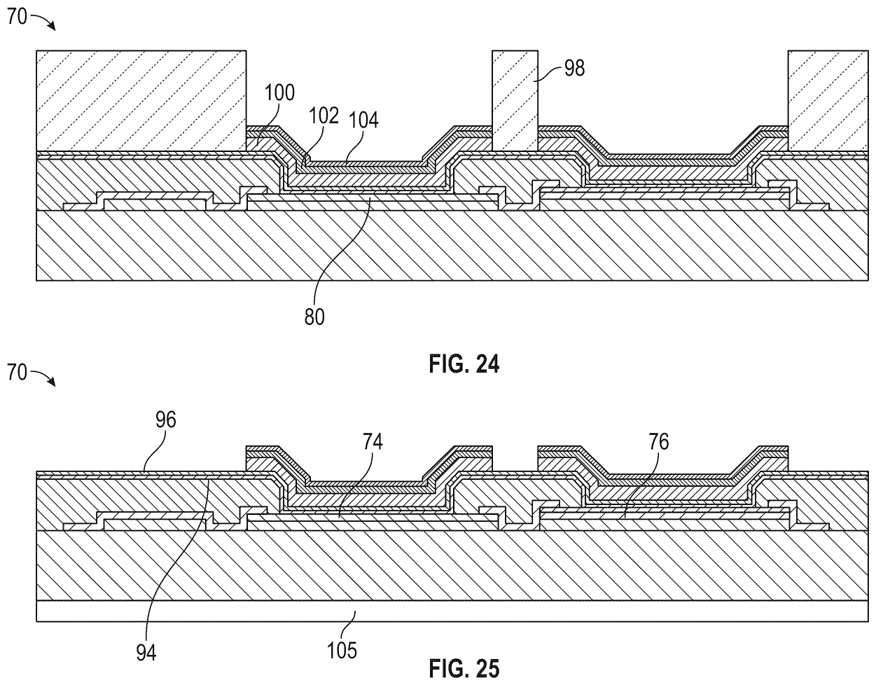

At this electroplating stage illustrated in FIG. 24, the power MOSFET implementation 70 is ready for electroplating in a way that generates sufficiently strong interconnects that can successfully complete a ribbon bonding operation or a wirebonding operation with a thick bond wire. As illustrated, three layers have been sequentially electroplated, one on top of the other. The first layer is a thick copper layer 100. In various method implementations, the thick copper layer 100 can be at least 18 microns thick. In various other implementations, the thick copper layer 100 can be about 20 microns thick. In a particular implementation, the thickness of the copper layer is about 10 microns thick. The thickness of the copper layer may be determined by the power dissipation requirements for the particular power MOSFET device (RDSon). The next layer is a thick nickel layer 102. In various method implementations, the nickel layer 102 may be about 5 microns thick. In a particular implementation, the thickness of the thick nickel layer may be between about 1 micron to about 30 microns thick. The thickness of the thick nickel layer 102 may be determined by the particular continuous operating temperature of the particular power MOSFET device and/or the mechanical/bonding requirements for the interconnect (solder reflow temperature profile, sintering process parameters, etc.). The next layer is gold layer 104 as gold is used in the implementation illustrated in FIG. 24. In other method implementation, however, a palladium layer may be electroplated instead. The thickness of the palladium layer in various implementations may be between about 0.05 microns to about 0.2 microns. The thickness of the gold layer 104 in various implementations may be about 0.15 microns to about 0.5 microns thick. In a particular implementation, the thickness of the gold layer 104 may be 0.5 microns. Because of the higher mechanical strength of the thick copper layer 100, thick nickel layer 102, and gold/palladium layer 104, the thickness of the first layer of aluminum silicon copper 80 can be reduced to about 1 micron to about 2 microns.

In various method implementations, following electroplating of the copper layer 100, an additional layer can be placed over the copper layer 100 to reduce/prevent continuing oxidation during the other electroplating operations. The additional layer may be, by non-limiting example, an organic layer that is removed as the nickel plating operation begins, a thin layer of copper oxide, or a 1-10 nanometer thick layer of a metal other than copper applied using atomic layer deposition. The use of the additional layer may help assist with prevent increasing resistance in the interconnect caused by the uncontrolled formation of copper oxide as the power MOSFET implementation 70 awaits nickel electroplating for a period of time that may vary from substrate to substrate.

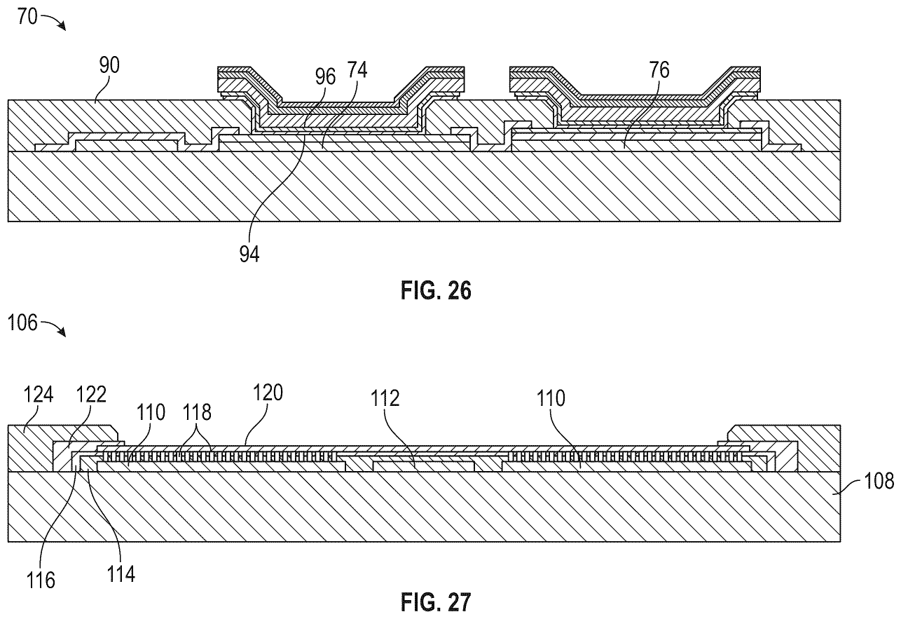

Referring to FIG. 25, the power MOSFET implementation 70 is illustrated following removal of the photoresist layer 98 using an ashing process, solvent stripping process or other method adapted for the particular material of the photoresist 98. FIG. 26 illustrates the power MOSFET implementation 70 following etching of the seed layer 96 and the barrier layer 94 from the passivation layer 90. The etching process may be carried out using an etching process selective to the material of the barrier layer 94 and seed layer 96 relative to the gold/palladium layer 104. At this point the source pad 74 and gate pad 76 are again electrically isolated from each other.

Also illustrated in FIG. 25 is the power MOSFET implementation 70 after formation of a backmetal layer (backmetal) 105 on a back side of the silicon carbide substrate. The backmetal layer may be formed of one layer or multiple layers of the same or dissimilar materials which may be, by non-limiting example, nickel, titanium nickel, nickel vanadium silver, nickel vanadium gold, aluminum nickel palladium gold, gold, palladium, aluminum silicon copper, or any combination thereof. The use of the backmetal may allow the power MOSFET implementation 70 to be cooled from both sides (dual side cooled) which may be a key capability where the device is operated under the extremely high stresses of 2000 V and higher and/or at high continuous operating temperatures. The stress of the backmetal thickness/material, etc. may also be adjusted to adjust the warpage of the silicon carbide substrate and/or the semiconductor die that is ultimately singulated form the silicon carbide substrate. As the use of thick copper and particularly thick nickel layers may significantly increase the stress on the surface of the semiconductor substrate which includes the pads, a corresponding increase in the thickness of the backmetal layer(s) may be implemented. The use of the backmetal layer thickness may be particularly helpful in managing the ultimate warpage of semiconductor die singulated from the semiconductor substrate after processing.

While the use of two layers of aluminum silicon copper to form the source pad 74 has been illustrated in the foregoing implementation, a single layer of aluminum silicon copper or aluminum silicon is possible, however, it requires the size of the pad to be larger than a two layer pad to deal with the stress of the pad. Thus the use of the two layers reduces stress. Reduced stress allows for smaller pads which allows for a smaller die size and the corresponding cost savings.

In the foregoing example, the use of a silicon carbide substrate has been illustrated. In various other device and method implementations, the substrate may also be a gallium nitride substrate structured for lateral GaN devices or vertical GaN devices. In various gallium nitride substrates, the entire substrate may be composed of gallium nitride or the substrate may include a layer of gallium nitride formed thereon.

The foregoing system and method implementations have involved pads formed of aluminum silicon copper. In other system and method implementations, the pads may be formed of only aluminum. Particular implementations include the use of two layers of aluminum as illustrated in FIGS. 20-32 to assist with stress reduction in a similar way as previously described. In these implementations, the thickness of the first aluminum layer on the source pads and gate pads would also be about 1 micron to about 2 microns instead of about 3 microns, enabled by the mechanical strength of the electrolytic plated copper/nickel/gold or palladium interconnect structure previously described. Because aluminum is sufficiently ductile, it is able to act as a stress buffer between the material of the die stack/silicon carbide substrate and the copper/nickel/gold layers of the interconnect during operation of the device.

Where the pads are made of only aluminum, in a particular implementation, the first layer of the pads may be made of copper while the second layer of the pads may be only aluminum. In such implementations, the aluminum may provide sufficient stress relief in a single layer to allow the first layer of the pads to be made of electroplated copper. In such implementations, the method of formation would be modified to include providing a silicon carbide substrate that includes a plurality of aluminum pads (as the second or bottom layer of the pads) thereon. A barrier layer and seed layer (which may be made of the same material in various implementations) are then formed over the aluminum pads and the remainder of the exposed surface of the silicon carbide surface. A photoresist layer is then applied and patterned to expose the aluminum pads. A copper electroplating process is then carried out to form the second layer of the pads made of copper. Following the electroplating process, the photoresist is removed using an ashing or solvent stripping process like any disclosed in this document. The seed layer is then etched using a process consistent with selective removal of the seed layer material. At this point the pads include a first layer of copper and a second layer of aluminum and are now ready for additional processing to finish forming the interconnect structure. In various implementations, the thickness of the first copper layer of the pads may be about 1 micron to bout 20 microns. In some implementations, the thickness of the first copper layer may be between about 2 microns to about 5 microns. The thickness of the first copper layer may be determined by various factors, including current carrying capacity, resistance, and mechanical stress during bonding.

Depending on the dimensions desired for the interconnect, because the first layer of the pad is copper, in a particular method implementation, the seed layer may not be etched and the photoresist layer may not be removed and additional copper electroplating using the existing seed layer may be carried out to form the bottom layer of the interconnect. This copper electroplating process is followed by electroplating of the nickel and gold/palladium layers as previously described. In such implementations, the same seed layer may be used to form the electrical connection to the pads to enable the electroplating, and it is etched away after electroplating is completed and removal of the photoresist layer is completed. Thus, in this method, no new seed layer may be needed to form the interconnect structure. In various method implementations, any of the copper oxidation control/prevention methods/systems previously described may be utilized to manage oxidation of the copper layer on the pads and/or the copper layer in the interconnect.

Where the interconnect structure is desired to be not substantially coextensive with the shape of the copper layer of the pads (wider, smaller, etc.), the method includes, after the photoresist layer is removed and the seed layer is removed, forming a passivation material around the pads (like a patterned polyimide or other material like those disclosed herein). A second barrier layer and seed layer (which may be of different materials or the same materials like any disclosed in this document) is then deposited over the copper layer of the pads and the passivation material. The thick copper layer of the interconnect is then electroplated followed by the electroplating of the thick nickel layer and the gold or palladium layer using processes like those previously described. The thicknesses of the thick copper, thick nickel and gold/palladium layers may be any of those previously described. In various method implementations, any of the copper oxidation control/prevention methods/systems previously described may be utilized to manage oxidation of the copper layer on the pads and/or the copper layer in the interconnect.

The foregoing discussion involves pad structures that formed of two layers of metal formed directly over each other. However, because the use of the electroplated copper/nickel/gold or palladium layers in the interconnect, a different pad design can be employed with a silicon carbide substrate to allow the gate runner to be routed below the source pad without the issues of interlayer dielectric cracking. This design allows for a reduction in the size of the resulting semiconductor die. Also, because this pad design involves planarizing various layers, it results in a structure that has less stress when formed on a silicon carbide substrate which increases its ability to handle operational stresses and stress testing successfully.

Referring to FIG. 27, an implementation of a source pad system 106 that includes planarized intermetal dielectric layers and/or passivation layers is illustrated. As illustrated, a silicon carbide substrate 108 is employed upon/within which is built the various components of a semiconductor device (though a gallium nitride substrate like any disclosed herein could be used). For the sake of easier illustration, none of the layers of the die stack below metal 1 are illustrated in the implementation of FIG. 27. As illustrated, pads 110 are formed on the silicon carbide substrate along with gate runner 112. The pads 110 and gate runner 112 in this implementation are formed of aluminum silicon copper. In other implementations, however, the pads 110 and gate runner 112 could be formed of aluminum silicon or just aluminum. Surrounding pads 110 and gate runner 112 is a first interlayer dielectric layer 114 which has been planarized. A second interlayer dielectric layer 116 has been formed over the first interlayer dielectric layer 114. A plurality of vias 118 have been formed through the first interlayer dielectric layer 114 and second interlayer dielectric layer 116. Source pad 120 is coupled over the plurality of vias 118 and the second interlayer dielectric layer 116 and over gate runner 112. In this implementation the source pad 120 is made of aluminum silicon copper, though it may be made of just aluminum in some implementations. The ability to planarize the first interlayer dielectric layer 114 (and in some implementations, the second interlayer dielectric layer 116) and the ability to route the gate runner below the source pad 120 allows the size of the source pad to be maximized which can enable better performance of the semiconductor device. First passivation layer 122 is presented around the perimeter of the source pad 120. In this implementation, the material of the first passivation layer 122 is a hard passivation material like a silicon nitride. Second passivation layer 124 is also formed over the first passivation layer 122, and in this implementation is a polyimide material to assist with providing compliant material adjacent to the subsequent interconnect.

The source pad system 106 is ready for processing using the foregoing methods of forming an interconnect like those disclosed herein including depositing a barrier layer and seed layer and then electroplating thick copper, thick nickel, and gold/palladium layers. Because the interlayer dielectric layers have been planarized and electroplating has been used to form the rest of the interconnect structures, the resulting source pad and interconnect can handle high continuous operation temperatures and operating voltages like those disclosed in this document.

While the source pad system 106 can be used with the interconnects disclosed herein, it may also be used with other interconnect types, or used for direct bonding using a wirebond or solder in various implementations. The principles disclosed herein can be used to construct various interconnect systems for source pads. Furthermore, the principles disclosed herein can be applied to full thickness or thinned silicon carbide or gallium nitride substrates where the thinning takes place prior to formation of the interconnects or afterward. The thickness of the thinned silicon carbide may range between about 100 microns to about 150 microns. In some implementations, the thickness of the thinned silicon carbide may be about 120 microns. For the gallium nitride, thinning of the silicon or sapphire substrate may take place to a desired level if mechanical thickness reduction is desired.

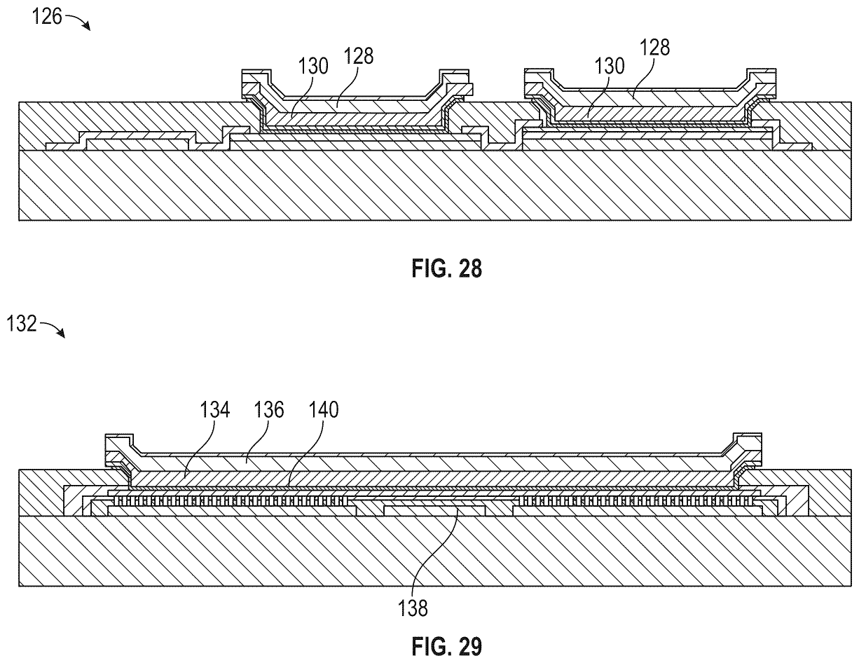

Referring to FIG. 28, an implementation of a power MOSFET system 126 is illustrated that includes a thick nickel layer 128 substantially the same thickness as the thick copper layer 130 is illustrated on a semiconductor substrate like any disclosed herein. The use of the thick nickel can assist with making the resulting interconnect more mechanically stiff and less likely to deform during a bonding operation with a ribbon bond or thick bond wire. FIG. 29 illustrates source pad system 132 with planarized pads on any semiconductor substrate disclosed herein like those illustrated in FIG. 27 following electroplating of a thick copper layer 134 and a thick nickel layer 136 thereon. In this implementation the thick nickel layer 136 is similar in thickness to the thickness of the thick copper layer 134. As previously noted, the use of the planarized structure in the source pad system 132 allows for the gate runner 138 to pass under the source pad 140. In both the implementations illustrated in FIG. 28 and FIG. 29, the use of a backmetal layer with a correspondingly thick layer of nickel therein may be used to manage stress and the ultimate warpage of semiconductor die cut from the semiconductor substrate.

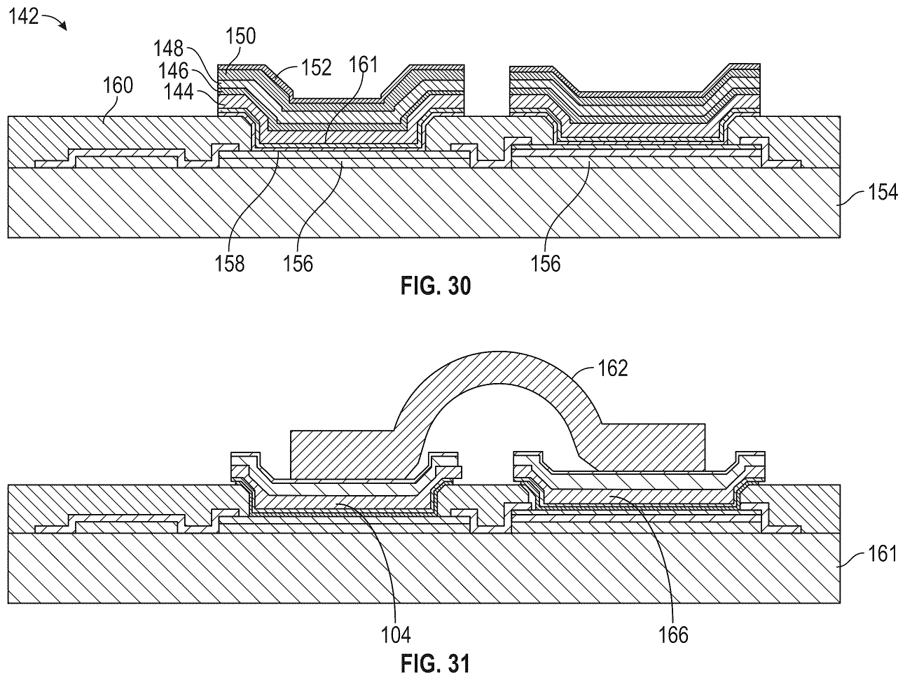

Referring to FIG. 30, another implementation of a semiconductor substrate 142 is illustrated that includes interconnects that have multiple layers of copper and multiple layers of nickel. The particular final thickness of the multi-layered interconnects can be determined by what is needed to mechanically handle the size/diameter of the ribbon bond or bond wire, the metallization type of the ribbon bond/bond wire, and the particular tooling used to form the bond between the ribbon bond/bond wire and the interconnects. In this implementation, a layer stack is formed beginning with first copper layer 144 followed by first nickel layer 146, then second copper layer 148 and the second nickel layer 150. Gold layer 152 (in this implementation) is then formed over second nickel layer 150 (though a palladium layer could also be used in various other implementations. In the stack, the thickness of the first and second copper layers 144, 148 may be the same or substantially the same. However, in various interconnect implementations, the thickness of the two layers may be different with the first copper layer 144 thicker or thinner than the thickness of the second copper layer 148.

The same is true of the first and second nickel layers 146, 150—the thickness of the two layers may be the same or substantially the same. In other interconnect implementations, the thickness of the two layers may be different with the first nickel layer 146 thicker or thinner than a thickness of the second nickel layer 150. In this implementation and in the other implementations of thick copper/thick nickel interconnects the thickness of the gold layer 152 (or palladium layer) may be determined by the amount needed to prevent oxidation of the underlying metal layers. In these implementations, the thickness may be between about 0.25 microns to about 0.5 microns of gold and between about 0.05 microns to about 0.2 microns for palladium. In a particular implementation, the thickness of first copper layer 114 is about 10 microns, the thickness of the first nickel layer is about 3 microns to about 4 microns, the thickness of the second copper layer is about 10 microns, the thickness of the second nickel layer is 3 to about 4 microns, and the thickness of the gold layer is about 0.5 microns.

Because the forces involved in bonding a thick bond wire or a ribbon bond can deform the underlying aluminum-containing pads and/or the device stack below the interconnect, the use of multiple layers of a hard metal material like nickel allows the interconnect to absorb the bonding stress. The ability of the interconnect to absorb the bonding stress serves to mechanically isolate the underlying aluminum-pads and the device stack below the pads. Because of this, the use of systems like die top systems (DTS) is not necessary. Also the need to sinter a ribbon bond to an interconnect and then bond additional ribbon bonds/bond wires to the more mechanically robust ribbon bond may not need to be used. This latter approach is a low throughput process that involves expensive materials.

The multi-layered interconnect implementation illustrated in FIG. 30 can be formed using a method of forming an interconnect. The method includes providing a semiconductor substrate 154 like any disclosed herein that includes a plurality of aluminum-containing pads 156 formed thereon. The aluminum-containing pads 156 may be made of aluminum silicon copper, aluminum silicon, or only aluminum in various implementations. A passivation material(s) 160 like any disclosed in this document surrounds the various pads. The various pads 156 may be source pads, gate pads, or another other pad type used in the particular semiconductor device(s) on the semiconductor substrate 154. The method includes forming a barrier layer 158 over the plurality of aluminum-containing pads and the passivation material. The material(s) of the barrier layer 158 may be any disclosed in this document. The method also includes forming a seed layer 161 over the barrier layer 158 which may be of any material disclosed in this document.

Following formation of the seed layer 161, preparations for various electroplating operations then take place. The method includes forming a layer of photoresist with a plurality of openings exposing the plurality of aluminum-containing pads over the seed layer 158. The method includes forming first copper layer 144 over the seed layer by electroplating into each opening of the plurality of openings to form a layer of a desired thickness, which may be a thick copper layer like those disclosed herein in various implementations. The method then includes forming a first nickel layer 146 over the first copper layer 144 using electroplating into each opening of the plurality of openings where the first nickel layer 146 may be a thick nickel layer like any disclosed in this document.

The method then includes forming a second copper layer 148 over the first nickel layer 146 using electroplating where the second copper layer 148 may also be a thick copper layer like any disclosed in this document. The method also includes forming second nickel layer 150 over the second copper layer 148 using electroplating where the second nickel layer 150 may be a thick nickel layer like those disclosed herein. The method also includes forming a gold layer 150 (or a palladium layer) over the second nickel layer 148. At this point, the photoresist layer is removed using ashing or solvent stripping or another method disclosed herein consistent with the material of the photoresist. Following the removal of the photoresist, the method includes etching the barrier layer 158 and the seed layer 161 using any appropriate etching method disclosed herein.

While the use of two copper layers and two nickel layers has been illustrated, additional copper and/or nickel layers (thick or otherwise) could be employed to develop an interconnect of the desired height and/or strength in various implementations. Accordingly, the method implementations could include electroplating steps that correspond with each additional layer(s) being formed. Those of ordinary skill will readily appreciate how to construct versions of interconnects with more than two layers of copper and/or more that two layers of nickel using the principles disclosed herein. The method may also include forming a backmetal on the side of the semiconductor substrate that opposes the side with the interconnects. In the various method implementations, the backmetal may be any backmetal implementation disclosed in this document.

At this point the resulting interconnect is ready for a bonding operation. The method includes bonding a ribbon bond or a bond wire to the gold layer 150 (or palladium layer) on the interconnect surface. In various implementations, the bond wire is at least 254 microns (10 mils) thick. Referring to FIG. 31, a semiconductor substrate 161 is illustrated following the formation of a ribbon bond 162 between the source interconnect 164 and gate interconnect 166. In this implementation a soldering or other non-sintering bonding operation is carried out that establishes the mechanical bond between the ribbon bond 162 and the material of the source interconnect 164 and gate interconnect 166. The nature of the ribbon bond 162 is illustrated here for the purposes of illustration, as the ribbon bond 162 can ultimately attach to any other pad or another package structure in various other implementations.

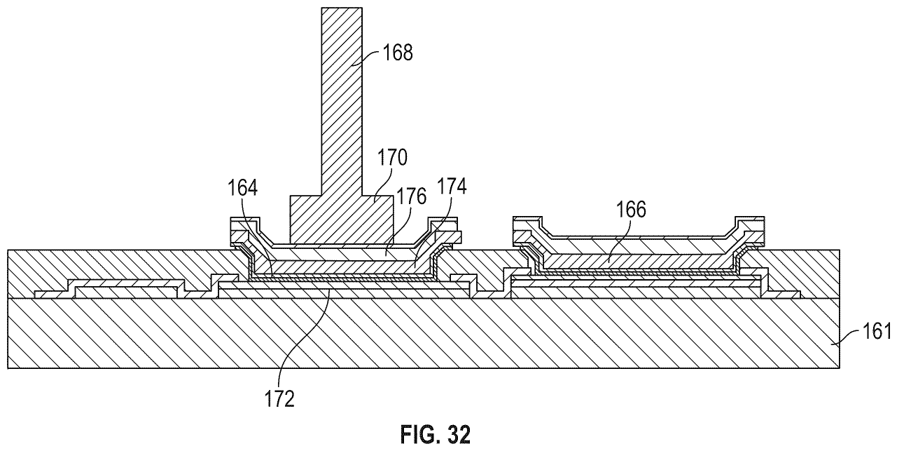

Referring to FIG. 32, the semiconductor substrate 161 is illustrated following wirebonding of a bond wire 168 that is at least 254 microns thick (10 mils) to the source interconnect 164. Here, due to the increased mechanical strength of the source interconnect, the wirebond 170 has been successfully formed without damaging the aluminum-containing pad 172 of the source interconnect due to the presence of the thick copper layer 174 and thick nickel layer 176. Similar bonding performance can be observed with the interconnect implementations like those illustrated in FIG. 30 which have multiple copper and multiple nickel layers. These implementations, however, may be able to handle larger bond wire diameters due to the higher mechanical strength of the multi-layer interconnects.

In places where the description above refers to particular implementations of copper pad metallization systems and implementing components, sub-components, methods and sub-methods, it should be readily apparent that a number of modifications may be made without departing from the spirit thereof and that these implementations, implementing components, sub-components, methods and sub-methods may be applied to other copper pad metallization systems.

What is claimed is:

1. A method of forming an interconnect comprising:
providing a semiconductor substrate comprising a plurality of aluminum silicon copper pads thereon, each pad surrounded by a passivation material;
forming a barrier layer over the plurality of aluminum silicon copper pads and the passivation material;
forming a seed layer over the barrier layer;
patterning a layer of photoresist with a plurality of openings exposing the plurality of aluminum silicon copper pads;
forming a copper layer at least 18 microns thick over each of the aluminum silicon copper pads by electroplating into each opening of the plurality of openings;
forming a nickel layer at least 5 microns thick over the copper layer;
forming one of a gold layer or a palladium layer over the nickel layer;
removing the layer of photoresist;
etching the barrier layer and the seed layer to form a plurality of copper-containing interconnects; and
bonding one of a ribbon bond or a bond wire at least 254 microns thick to one of the gold layer or the palladium layer.

2. The method of claim 1, wherein forming the copper layer, the nickel layer, and the one of the gold layer or the palladium layer on each aluminum silicon copper pad of the plurality of aluminum silicon copper pads further comprises forming using electrolytic plating.

3. The method of claim 1, wherein the semiconductor substrate comprises silicon carbide.

4. The method of claim 1, wherein forming the barrier layer or the seed layer further comprises using sputtering.

5. The method of claim 1, further comprising forming a backmetal on the semiconductor substrate.

6. The method of claim 1, wherein each aluminum silicon copper pad of the plurality of aluminum silicon copper pads is formed of a top layer of aluminum silicon copper that contacts the barrier layer and a bottom layer of aluminum silicon copper.

7. The method of claim 6, wherein the top layer of aluminum silicon copper is 1 micron thick.

8. A method of forming an interconnect comprising:
providing a semiconductor substrate comprising a plurality of aluminum pads thereon, each pad surrounded by a passivation material;
forming a barrier layer over the plurality of aluminum pads and the passivation material;
forming a seed layer over the barrier layer;
patterning a layer of photoresist with a plurality of openings exposing the plurality of aluminum pads;
forming a copper layer at least 18 microns thick over each of the aluminum pads by electroplating into each opening of the plurality of openings;
forming a nickel layer at least 5 microns thick over the copper layer;
forming one of a gold layer or a palladium layer over the nickel layer;
removing the layer of photoresist;
etching the barrier layer and the seed layer to form a plurality of copper-containing interconnects; and
bonding one of a ribbon bond or a bond wire at least 254 microns thick to one of the gold layer or the palladium layer.

9. The method of claim 8, wherein forming the copper layer, the nickel layer, and the one of the gold layer or the palladium layer on each aluminum pad of the plurality of aluminum pads further comprises forming using electrolytic plating.

10. The method of claim 8, wherein the semiconductor substrate comprises silicon carbide.

11. The method of claim 8, wherein forming the barrier layer or the seed layer further comprises using sputtering.

12. The method of claim 8, further comprising forming a backmetal on the semiconductor substrate.

13. The method of claim 8, wherein each aluminum pad of the plurality of aluminum pads is formed of a top layer of aluminum that contacts the barrier layer and a bottom layer of aluminum.

14. The method of claim 13, wherein the top layer of aluminum is 1 micron thick.

15. A method of forming an interconnect comprising:
providing a semiconductor substrate comprising a plurality of aluminum-containing pads thereon, each pad surrounded by a passivation material;
forming a barrier layer over the plurality of aluminum-containing pads and the passivation material;
forming a seed layer over the barrier layer;
patterning a layer of photoresist with a plurality of openings exposing the plurality of aluminum-containing pads;
forming a first copper layer over each of the aluminum-containing pads by electroplating into each opening of the plurality of openings;
forming a first nickel layer over the first copper layer;
forming a second copper layer over the first nickel layer by electroplating into each opening of the plurality of openings;
forming a second nickel layer over the second copper layer;
forming one of a gold layer or a palladium layer over the second nickel layer;
removing the layer of photoresist;
etching the barrier layer and the seed layer to form a plurality of copper-containing interconnects; and
bonding one of a ribbon bond or a bond wire at least 254 microns thick to one of the gold layer or the palladium layer.

16. The method of claim 15, wherein a combined thickness of the barrier layer, seed layer, first copper layer, first nickel layer, second copper layer, second nickel layer, and the one of the gold layer or palladium layer is sufficient to successfully complete the bonding of the one of the ribbon bond or the bond wire.

17. The method of claim 15, wherein the first copper layer and the second copper layer are 10 microns thick.

18. The method of claim 15, wherein the first nickel layer and the second nickel layer are between 3 microns and 4 microns thick.

19. The method of claim 15, further comprising forming a backmetal layer on a surface of the semiconductor substrate opposing a surface of the semiconductor substrate comprising the plurality of aluminum-containing pads.

20. The method of claim 15, wherein each aluminum-containing pad of the plurality of aluminum-containing pads is formed of a top layer that contacts the barrier layer and a bottom layer and where the top layer is 1 micron thick.
